(19) United States
(12) Patent Application Publication
(10) Pub. No.: US 2002/0040961 A1
(43) Pub. Date: Apr. 11, 2002

(54) Solid-state image pick-up device and fingerprint collating apparatus using the same

(75) Inventors: Fuyuki Okamoto, Tokyo (JP); Teruyuki Higuchi, Tokyo (JP); Yoshinori Muramatsu, Tokyo (JP)

Correspondence Address: SUGHRUE, MION, ZINN, MACPEAK, & SEAS, 2100 Pennsylvania Avenue, N.W., Washington, DC, 20037, US

(73) Assignee: NEC CORPORATION

(21) Appl. No.: 09/964,500

(22) Filed: Sep. 28, 2001

(30) Foreign Application Priority Data
Oct. 4, 2000 (JP) 305222/2000

(51) Int. Cl. H01L 27/00

(52) U.S. Cl. 250/208.1

(57) ABSTRACT

The present invention provides a solid-state image pick-up device which is capable of displaying its image pick-up ability more than that of the related art. A sensor array is composed of photoelectric conversion cells arranged in the form of a matrix. An X scanner and a Y scanner scan the respective photoelectric conversion cells. A VGA amplifies output voltages of the respective photoelectric conversion cells, and an ADC converts an output voltage of the VGA into digital data. An average computing unit computes the average value of output voltages of the respective photoelectric conversion cells in a predetermined area of the sensor array on the basis of the output of the ADC. A divider divides a reference value by the average value and outputs the result of division to a multiplier. The multiplier multiplies together the output of a register having a gain control signal for the previous frame stored in it and the output of the divider, and outputs the result of multiplication to the VGA as a gain control signal. Since this device controls the gain of the VGA on the basis of the average value of outputs of photoelectric conversion cells in the specific area, it can precisely perform a gain adjustment.

### BACKGROUND OF THE INVENTION

1. Field of the Invention

The present invention relates to a solid-state image pick-up device. Specifically, the present invention includes an improvement over an amplifier circuit at the output side of a sensor array comprising photoelectric conversion cells. The present application claims priority from Japanese Patent Application No. 305222/2000, filed on Oct. 4, 2000, the contents of which are incorporated herein by reference.

2. Description of the Related Art

FIG. 1 is a block diagram showing a conventional solid-state image pick-up device. A sensor array 1 has a number of photoelectric conversion cells arranged in the form of a matrix. An X scanner 2 scans the photoelectric conversion cells of the sensor array 1 in the X direction (horizontal direction). Likewise, a Y scanner 3 scans the respective photoelectric conversion cells of the sensor array 1 in the Y direction (vertical direction). A VGA (Variable Gain Amplifier) 5 amplifies the respective photoelectric conversion cell voltages, successively output from the sensor array 1. Further, the VGA amplifies an input signal at an amplification factor according to a control signal. An ADC (A-D converter) 6 converts an output from VGA 5 into digital data. The output from the ADC 6 is applied to an output terminal 7. An average computing unit 8 computes the average value of outputs of the ADC 6, namely, the average value of output voltages of the respective photoelectric conversion cells of the sensor array 1. A divider 9 divides a predetermined reference value by the output of the average computing unit 8, and the output of the divider 9 is applied to the gain control terminal of the VGA 5. Therefore, the average value of data output from the output terminal 7 is controlled to coincide with the reference value.

In this way, a conventional solid-state image pick-up device computes the average of output voltages of all the photoelectric conversion cells of the sensor array 1 using the average computing unit 8; Based on this average the gain of the VGA is controlled.

However, controlling the gain of the VGA 5 on the basis of the average of output voltages of all the photoelectric conversion cells of the sensor array 1 may not be sufficient and in some cases inaccurate for certain applications using the solid state image pick-up device. In such case, at least it is not possible to sufficiently and completely unlike ability of the solid-state image pick-up device.

The present invention overcomes the problem noted above in relation to conventional solid-state image pick up devices.

### SUMMARY OF THE INVENTION

According to one aspect of the present invention, there is provided, a solid-state image pick-up device comprising a sensor array having a plurality of photoelectric conversion cells arranged in the form of a matrix, an amplifying means for amplifying outputs of the photoelectric conversion cells successively outputted from the sensor array, and an analog-to-digital converter for converting the output of the amplifying means into digital data, wherein the solid-state image pick-up device comprising an average computing means for computing the average value of outputs of photoelectric conversion cells in a predetermined specific area of the sensor array on the basis of the output of the analog-to-digital converter, and a converting means for converting the result of computation of the average computing means into a gain control signal for controlling the gain of the amplifying means.

A second aspect of the present invention provides a solid-state image pick-up device, wherein the converting means is a divider for dividing a predetermined reference value by the output of the average computing means.

A third aspect of the present invention provides a solid-state image pick-up device, wherein the converting means is further comprises a register for storing a gain control signal of the previous frame and a multiplier for multiplying together the output of the divider and the output of the register, and the converting means outputs the output of the multiplier as a gain control signal.

A forth aspect of the present invention provides a solid-state image pick-up device, wherein the average computing means is provided with a timing detection means for detecting the timing when data of the photoelectric conversion cells in the specific area are outputted from the analog-to-digital converter on the basis of a clock pulse for scanning the sensor array, a totalizing means for totalizing in order the outputs of the analog-to-digital converter at timing of detection of the time detecting means, and a divider for dividing the result of totalization of the totalizing means by the number of photoelectric conversion cells in the specific area.

A fifth aspect of the present invention provides a solid-state image pick-up device, wherein the timing detection means is provided with a register for loading data of the input terminal at timing of the clock pulse, an adder for adding “1” to the output of the register and outputting the result of addition to the input terminal of the register, and a comparator for outputting a detection signal when the output of the adder coincides with the coordinates of the specific area.

A sixth aspect of the present invention provides a solid-state image pick-up device, wherein the timing detection means is provided with an address decoder for outputting a “1” signal at timing of scanning the specific area, and a circuit for outputting a timing detection signal when the output of the address decoder and a scanning signal for scanning the sensor array each are “1”.

A seventh aspect of the present invention provides a solid-state image pick-up device, wherein the totalizing means is provided with a selector for selecting and outputting the output of the analog-to-digital converter at a detection timing of the timing detection means and outputting 0 at the other timing, a register for loading data of the input terminal at timing of the clock pulse, and an adder for adding the output of the selector to the output of the register and outputting the result of addition to the input terminal of the register.

A eighth aspect of the present invention provides a solid-state image pick-up device, comprising a means for computing the number of photoelectric conversion cells, the means being composed of a computing means for computing the number of photoelectric conversion cells in the X direction and the number of photoelectric conversion cells in the Y direction of the specific area on the basis of the coordinates of the start point and the coordinates of the end point of the specific area, and a multiplying means for multiplying together the number of photoelectric conversion cells in the X direction and the number of photoelectric conversion cells in the Y direction computed by the computing means.

A ninth aspect of the present invention provides a solid-state image pick-up device, wherein a plurality of the specific areas are set in advance, and the average computing means computes the average value of outputs of photoelectric conversion cells in a specific area selected by a user.

A tenth aspect of the present invention provides a fingerprint collating apparatus comprising an illuminating means for irradiating light to a finger, an optical system for leading the light reflected by the finger to the sensor array of a solid-state image pick-up device of the present invention, an extracting means for extracting feature points of a fingerprint of the finger from the output of the solid-state image pick-up device of the present invention, a storage means for storing feature points of a plurality of fingerprints in it, and a collating means for collating the feature points extracted by the extracting means and the feature points stored in the storage means with each other.

Another aspect of the present invention provides a fingerprint collating apparatus further comprising a detecting means for detecting the position of a finger on the basis of the output of the solid-state image pick-up device of the present invention, and a means which obtains and outputs the start point and the end point of the specific area from the result of detection of the detecting means to the solid-state image pick-up device of the present invention.

### BRIEF DESCRIPTION OF THE DRAWINGS

The above and other objects, advantages and features of the present invention will be more apparent from the following description taken in conjunction with the accompanying drawings, in which:

FIG. 1 is a block diagram showing the composition of a solid-state image pick-up device as a related art;

FIG. 2 is a block diagram showing the composition of a first embodiment of the present invention;

FIG. 3 is a circuit diagram showing details of an average computing unit 11 and an average computation control unit 12 in the first embodiment;

FIG. 4 is a block diagram showing the composition of a circuit for computing the number of photoelectric conversion cells in the first embodiment;

FIG. 5 is a circuit diagram showing the composition of an average computation control unit 12 in a second embodiment of the present invention;

FIG. 6 is a block diagram showing the composition of a third embodiment of the present invention;

FIGS. 7A and 7B are a figure. for explaining the operation of the third embodiment;

FIGS. 8A and 8B are an explanatory diagram for explaining the operation of a fourth embodiment of the present invention; and

FIG. 9 is a block diagram showing the composition of a fifth embodiment of the present invention.

### BRIEF DESCRIPTION OF THE INVENTION

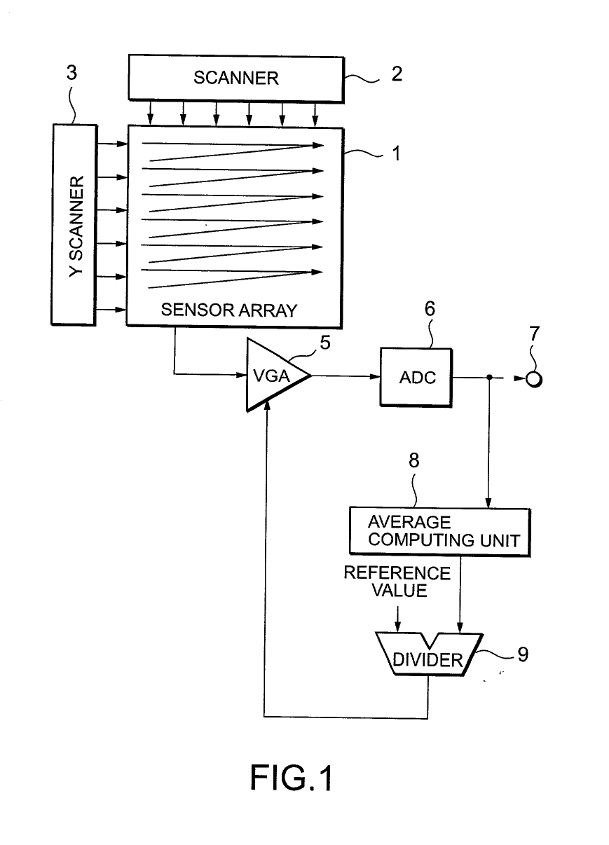

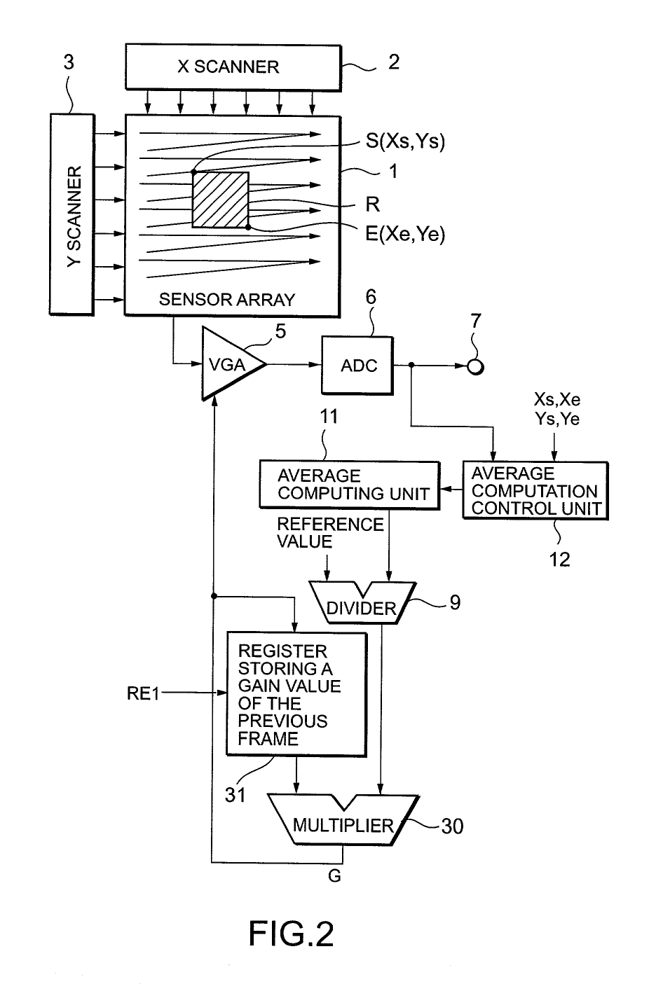

Embodiments of the present invention are described with reference to the drawings in the following. FIG. 2 is a block diagram showing the composition of a solid-state image pick-up device according to a first embodiment of the present invention. In FIG. 2, components corresponding to the respective components of the conventional device shown in FIG. 1 are referred to using the same symbols as those of the device. As shown in FIG. 1, the solid state image pick up device comprises a sensor array 1, an X scanner 2, a Y scanner 3, a VGA 5 for amplifying output voltages of the respective photoelectric conversion cells of the sensor array 1, an ADC 6 for converting the output of the VGA 5 into digital data, an output terminal 7. An average computing unit 11 computes the average value of output voltages of the respective photoelectric conversion cells in a predetermined area R of the sensor array 1 on the basis of the output of the ADC 6. An average computation control unit 12 is attached to the above-mentioned average computing unit 11.

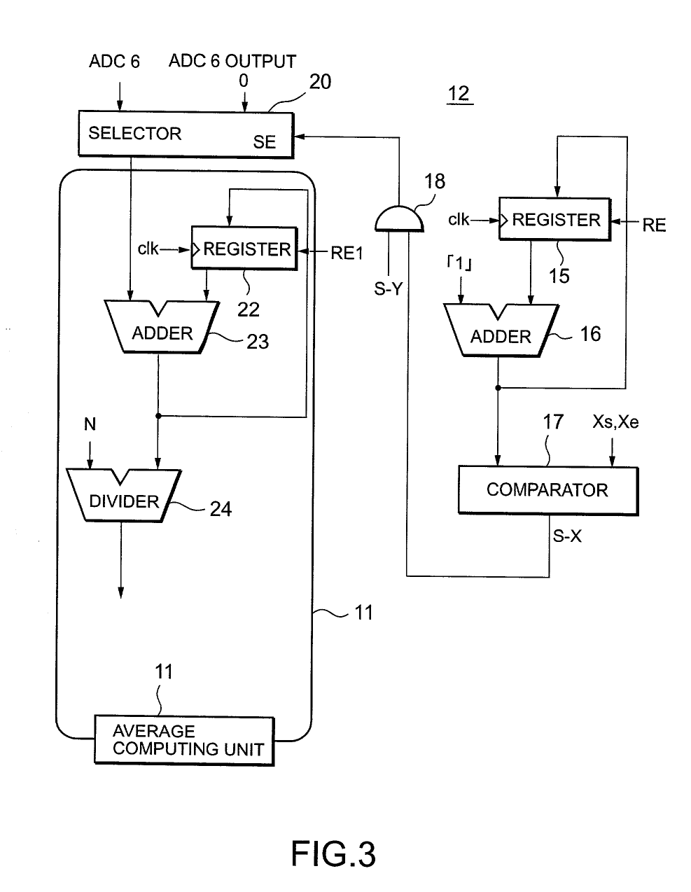

FIG. 3 is a circuit diagram showing further details of the abovementioned average computing unit 11 and average computation control unit 12. A register 15 loads input data according to timings set by a clock pulse clk. The register 15 is reset by a reset signal RE. The clock pulse clk is a clock pulse used while the X scanner 2 scans the photoelectric conversion cells of the sensor array 1. On the other hand, the reset signal is a signal that is outputted immediately before the X scanner 2 starts scanning the sensor array 1. An adder 16 adds “1” to the output of the register 15 and outputs the result of the addition to an input terminal of the register 15 and an input terminal of a comparator 17. After resetting by the reset signal RE, the output of the register 15 is incremented by “1” at every pulse of the clock pulse clk. Therefore, the output of adder 16 determines the scanning position of the x scanner.

A comparator 17 compares the output of the adder 16 respectively with the X coordinate Xs of the start point and the X coordinate Xₑ of the end point of an area R (shown in FIG. 2). The comparator outputs a “1” signal when the output of the adder 16 is larger than coordinate Xₛ but smaller than coordinate Xe. In other words, an output signal S-X of this comparator 17 is “1” when the X scanner 2 is scanning between coordinate Xₛ and coordinate Xₑ. And this signal S-X is applied to the first input terminal of an AND gate 18. Although not illustrated, a similar circuit is provided for the Y scanner 3. This circuit for the Y scanner and outputs a signal S-Y to the AND gate 18; The signal S-Y is “1” when the Y scanner 3 is scanning between the Y coordinate Yₛ of the start point S and the Y coordinate Yₑ of the end point E. Therefore, the output of the AND gate 18 is a “1” signal when the area R is being scanned by both the X scanner 2 and the Y scanner 3; This “1” signal is applied to a select terminal SE of a selector 20. When the select terminal SE receives a “1”, the selector 20 selects and outputs the output of the ADC 6 to the average computing unit 11. On the other hand, when the select terminal S receives a “0”, it selects and outputs data “0”.

In the average computing unit 11, a register 22 loads input data at timing of the clock pulse clk. When a reset signal RE1 is active, the register 22 keeps the same value even if the clk is pulsed. The clock pulse clk is a clock pulse used while the above-mentioned X scanner 2 scans the respective photoelectric conversion cells of the sensor array 1. The reset signal RE1 is a signal that is outputted immediately before scanning the sensor array 1 is started. An adder 23 adds the output of the selector 20 to the output of the register 22 and outputs the result of addition back to an input terminal of the register 22. The adder 23 also outputs the result of the addition to an input terminal of a divider 24. The register 22 and the adder 23 add successively output values of the respective photoelectric conversion cells in the area R and output the result of addition to the divider immediately after the end point has been scanned. This result of addition is retained until scanning all the photoelectric conversion cells of the sensor array 1 is completed, and is reset immediately before scanning the next frame.

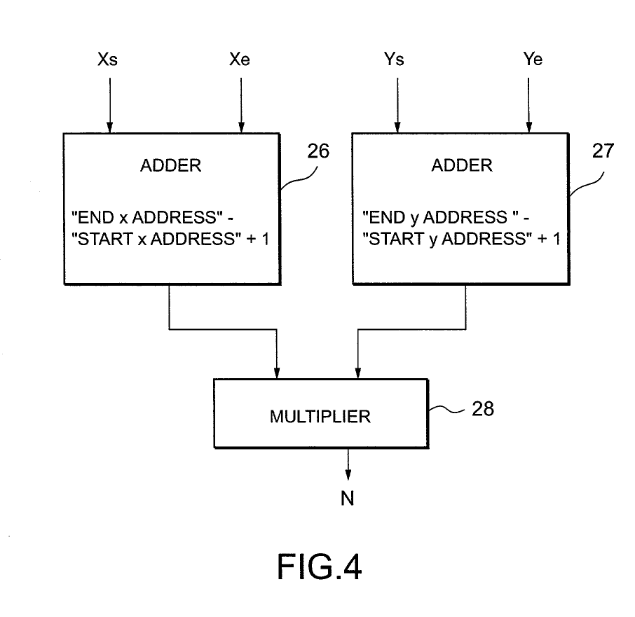

The divider 24 divides the output of the adder 23 by the number N of photoelectric conversion cells in the area R, and outputs the result of division to a divider 9 (shown in FIG. 2). The result of division corresponds to the average value of output voltages of the respective photoelectric conversion cells in the area R. FIG. 4 shows an example circuit for obtaining the number N of photoelectric conversion cells in the area R. An adder 26 subtracts the X address Xₛ of the start point S from the X address Xₑ of the end point E of the area R, and adds “1” to the result of subtraction and outputs the result of addition to a multiplier 28. Similarly, an adder 27 subtracts the Y address YS of the start point S from the Y address Yₑ of the end point E of the area R, and adds “1” to the result of subtraction and outputs the result of addition to the multiplier 28. The multiplier 28 multiplies together the outputs of the adders 26 and 27, and outputs the result of multiplication as the number N of photoelectric conversion cells to the divider 24 of FIG. 3.

Next, in FIG. 2, when all the photoelectric conversion cells of the sensor array 1 have been scanned, the divider 9 divides a predetermined reference value by the output of the average computing unit 11 and outputs the result of division to a multiplier 30. The multiplier 30 multiplies the output of the divider 9 by the output of a register 31 and outputs the result of multiplication as a gain control signal G for the VGA 5. The register 31 receives the above-mentioned reset signal RE1 and loads a gain control signal G, and stores a gain control signal of the previous frame.

The functionality and the need for register 31 and multiplier 30 are provided herein. Initially, the case where the output of the divider 9 is applied directly to the VGA 5 as in the conventional device of FIG. 1, is explained. Assuming that the output of the divider 9 is, for example “3” when the scanning operation of the sensor array 1 has ended, the output of the sensor array 1 is tripled in the VGA 5 at the time of the scanning of the next frame, and then is converted into digital data in the ADC 6, and is applied to the average computing unit 11. And in this case, since the output of the sensor array 1 has been tripled, even if the output of the sensor array 1 is exactly the same as that in the scanning of the previous frame, the output of the divider 9 is “1” and this data “1” is applied to the VGA 5. Due to this, in the scanning of the next frame, the output of the sensor array 1 is multiplied by one in the VGA 5 and is applied to the average computing unit 11 through the ADC 6, and as the result the output of the divider 9 becomes “3” again. In such a way, applying the output of the divider 9 directly to the VGA 5 causes a problem that the output of the VGA 5 is abnormally changed although the output of the sensor array 1 is not changed.

On the other hand, using the multiplier 30 and register 31 the device can be made to operate difficulty as follows. Assuming that the output of the divider 9 is, for example, “3” when the scanning has been completed, if the initial value of the register 31 is “1”, “3” is outputted from the multiplier 30. And when the next frame is scanned, the output of the sensor array 1 is tripled in the VGA 5, is converted into digital data in the ADC 6, and is applied to the average computing unit 11. When scanning is completed, data “3” output from the multiplier 30 is loaded into the register 31 and then is divided by the divider 9. In this case, since the output of the sensor array 1 has been tripled by the VGA 5, even if the output of the sensor array 1 is exactly the same as that while scanning the previous frame, the output of the divider 9 is “1” and this data “1” is applied to the multiplier 30. The multiplier 30 multiplies together this data “1” and the output data “3” of the register 31, and outputs the result of multiplication “3” to the VGA 5. Therefore, while scanning of the next frame, the output of the sensor array 1 is tripled again in the VGA 5.

Clearly, the multiplier 30 and register 31, help in performing the computation accurately.

Explanation of the above description by means of expressions is as follows.

First,

(the Nth frame ADC output)=(the (N−1)th frame gain)×(the nth frame analog output) equation 1.

Therefore,

(reference value)÷(the Nth frame digital average value)=(reference value)÷((the (N−1)th frame gain)×(the Nth frame analog output average value)) equation 2

When equation 2 is transformed the following is obtained:

(reference value)÷(the Nth frame digital average value)×(the (N−1)th frame gain)=(reference value)÷(the Nth frame analog output average value) equation 3

The circuit of FIG. 2 implements equation 3.

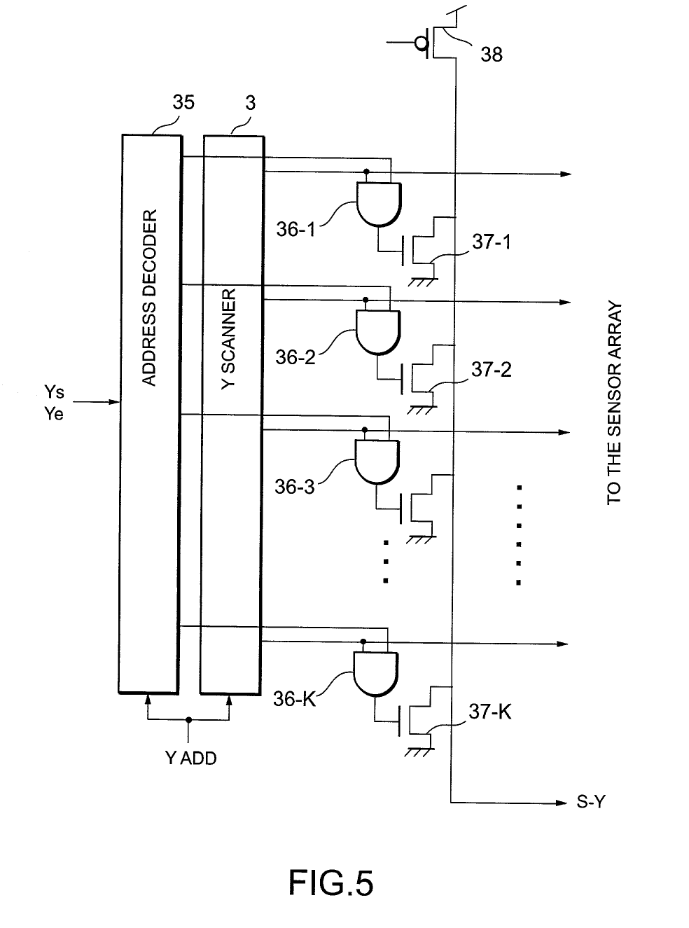

Next, other embodiments of the present invention are described. FIG. 5 is a circuit diagram showing a part of the structure of an average computation control unit 12 according to a second embodiment of the present invention. The circuits shown in FIG. 5 are circuits in lieu of register 15, adder 16 and comparator 17 in FIG. 3. But, the circuits in FIG. 5 are used in case of the Y direction control. An address decoder 35 data that indicates whether the Y scanner 3 should scan a specific position. It outputs a “1” when Y_{add} is larger than Yₛ and smaller than Yₑ. It outputs a “0” otherwise output terminal when data Y_{add} is larger than the Y coordinate Ys of the start point of area R and smaller than the coordinate Ye of the end point.

Outputs of the address decoder 35 are respectively output to AND gates 36-1, 36-2, . . . , 36-K (K: the number of rows of the sensor array 1) together with outputs of the Y scanner 3. The AND gates 36-1, 36-2, . . . , 36-K each indicate a circuits for performing on “AND” operation of an output of the address decoder and an output of the Y scanner 3. Outputs of the AND gates 36-1, 36-2, . . . , 36-K are respectively applied to the gates of FETs (field effect transistors) 37-1, 37-2, . . . , 37-K. In the FETs 37-1, 372, . . . , 37-K, their drains are connected together to the drain of an FET 38 as a load resistance, and their sources are grounded. And a signal of the common connection line of the respective drains is applied to the AND gate 18 shown in FIG. 3 as a signal S-Y.

In this structure, when the Y scanner 3 scans the coordinates Yₛ to Yₑ, output of a corresponding AND gate 36 becomes “1” and FET 37 is turned on and signal S-Y becomes “1”. Therefore, this circuit performs a similar operation to the circuit using the register 15, adder 16 and comparator 17 in FIG. 3.

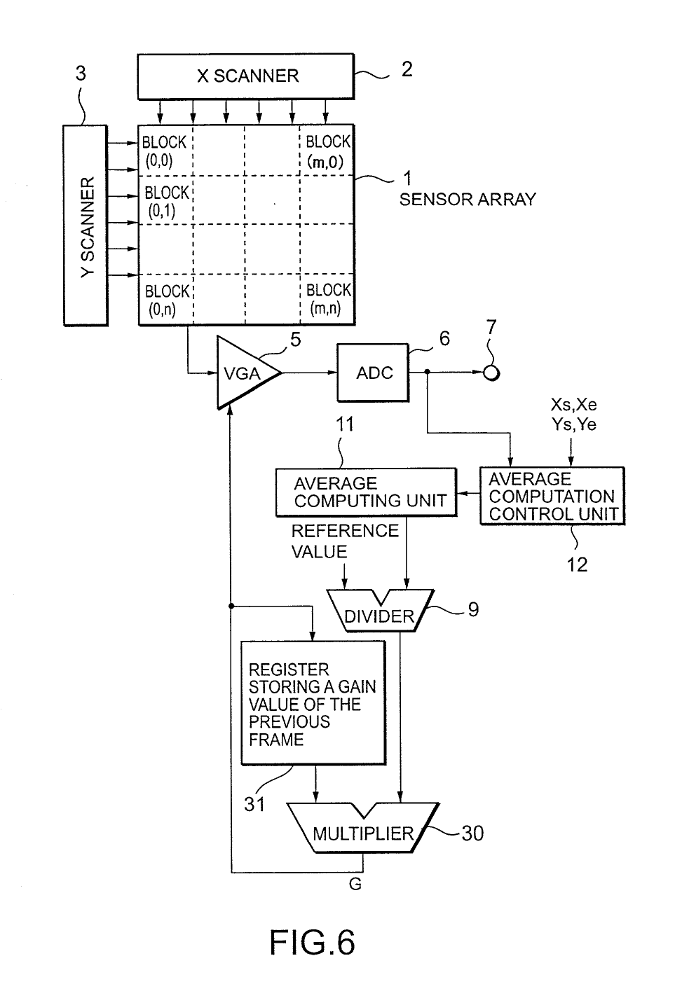

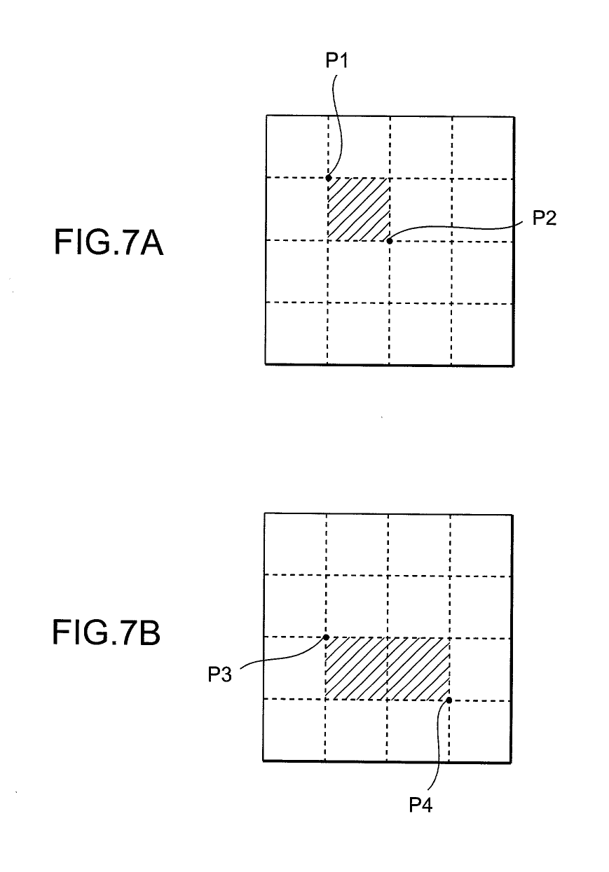

FIG. 6 is a block diagram showing the composition of a solid-state image pick-up device according to a third embodiment of the present invention, and the device shown in FIG. 6 is different from that shown in FIG. 2 at least in that the sensor array 1 is virtually divided into blocks (0, 0) to (m, n) thereby constituting (m×n) blocks. In other words, when a user specifies a block Only, the coordinates of the start point and end point of the specified block out of the X and Y coordinates of the start and end points of all the blocks stored in advance in a storage unit (not shown) are read out, and are input to the average computation control unit 12. Due to this, the average value of only the specified block is computed in the average computing unit 11. For example, when a block as shown in FIG. 7A is specified, the X and Y coordinates of the start point P1 and the end point P2 shown in FIG. 7A are output to in the average computation control unit 12, and in case that two consecutive blocks are specified as shown in FIG. 7B, the X and Y coordinates of the start point P3 and the end point P4 shown in FIG. 7B output to the average computation control unit 12.

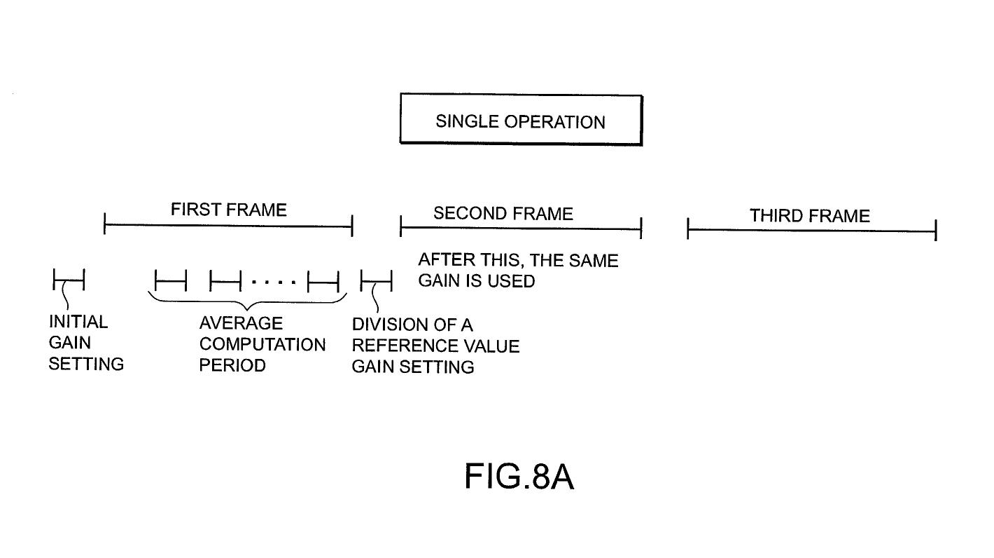

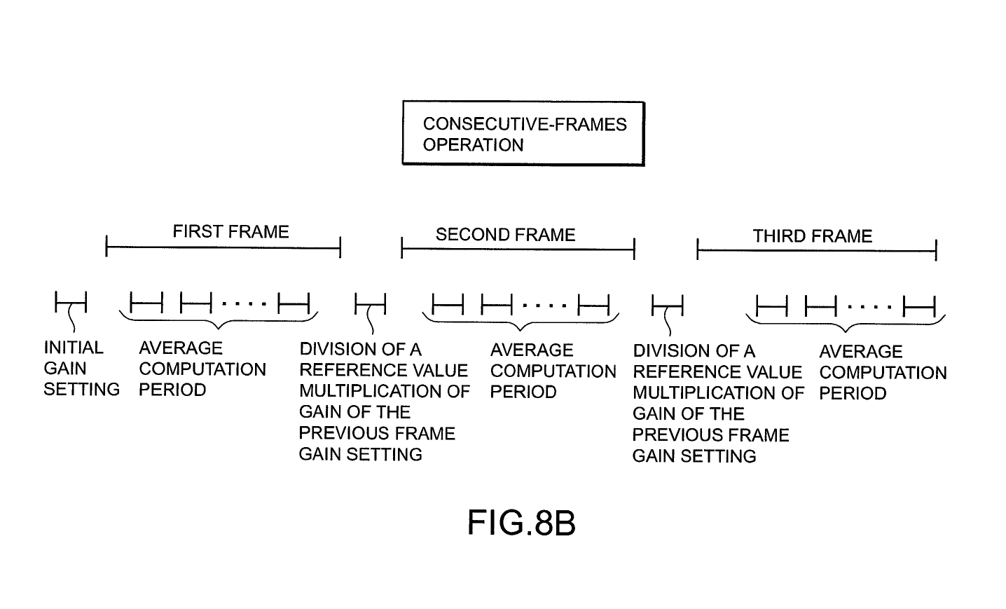

FIG. 8A is an explanatory diagram for explaining the operation of a solid-state image pick-up device according to a fourth embodiment of the present invention. When the power is turned on or a reset button is operated, this fourth embodiment sets forcibly the gain of the VGA 5 in FIG. 2 at “1” and the sensor array 1. An output obtained by the divider 9 is retained by a holding circuit (not shown). The output of the holding circuit is applied to the gain control terminal of the VGA 5. That is to say, in this fourth embodiment, an average computing operation in the average computing unit 11 is a single operation as shown in FIG. 8A; According to this, once a gain is determined, this gain is successively used in the following frame. For reference, a consecutive-frames operation by the circuit of FIG. 2 is shown in FIG. 8B.

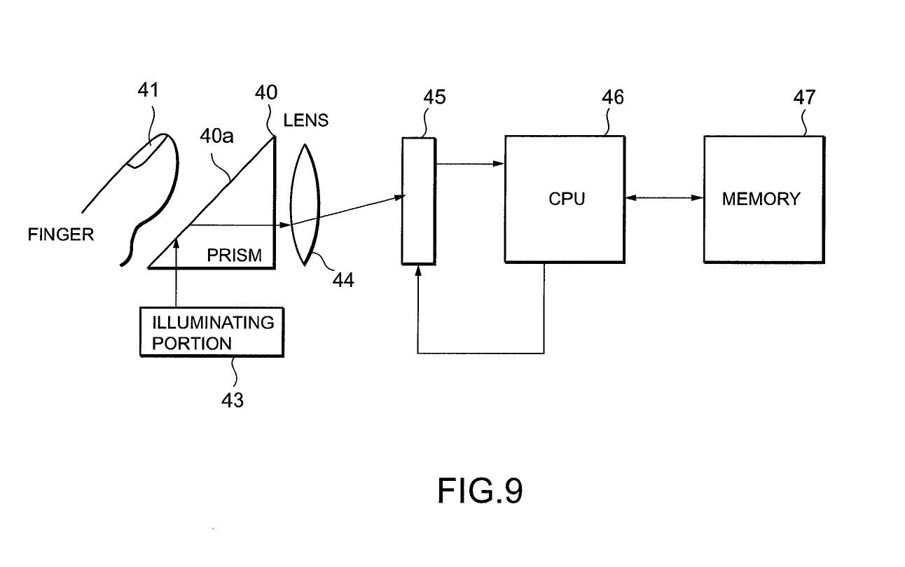

FIG. 9 is a block diagram showing the composition of a fingerprint collating apparatus according to a fifth embodiment of the present invention. A prism 40 comprises a face 40a that is used as a holding face to have a finger 41. An illuminating portion 43 emits light to the holding face 40a of the prism 40. A lens 44 forms a light which is emitted from the illuminating portion 43 and reflected by the finger 41 into an image on the sensor array 1 of a solid-state image pick-up device 45.

The solid-state image pick-up device 45 is similar to the device shown in FIG. 2, The image data output from the output terminal 7 is applied to a CPU (central processing unit) 46. The CPU 46 detects feature points of a fingerprint of the finger 41 from output data of the solid-state image pickup device 45. Next, the fingerprint is identified by collating the detected feature points with feature point data of fingerprints of a large number of people stored in advance in a memory 47.

In case that a definite result of collation cannot be obtained in the above process, the area R of FIG. 2 is changed to another area. As a method for performing this change, in case that a block to be detected is set in advance as shown in FIG. 6, a user tries to change specification of the block. In case that no block has been specified, a user changes the coordinates of the start point S and the end point E.

Alternately, the system itself can detect the position at which the finger is held, as described herein. In other words, what position on the holding face 40a a finger 41 is held to is not predetermined and the position in which the finger is held may greatly vary depending upon the person. Clearly, if the area R is fixed in position, the gain of the VGA 5 might be insight determined on the basis of the average in a position considerably different from the position of the finger 41. In such a case, the fingerprint cannot be accurately detected. On the other hand, a position at which a finger 41 is held and a position at which the finger is not held vary greatly in terms of the quantity of light which the sensor array 1 receives. Accordingly, it is possible to detect roughly a position at which the finger 41 is held on the basis of outputs of the respective photoelectric conversion cells of the sensor array 1. Thus, the CPU 46 detects the position of the finger 41 on the basis of the output of the solid-state image pick-up device 45, determines the start point S and the end point E from the result of detection, and outputs their coordinates (Xₛ, Yₛ) and (Xₑ, Yₑ) to the solid-state image pick-up device 45.

As described above, a solid-state image pick up device according to the present invention comprises an average computer which computes the average value of outputs of photoelectric conversion cells in a predetermined specific area of a sensor array on the basis of the output of an analog-to-digital converter and a converter which converts the result of computation of the average computing means into a gain control signal for controlling the gain of an amplifier. Using this structure, it is possible to enhance the pick up ability.

In another aspect of the present invention, a solid-state image pick up device further comprises a register for storing a gain control signal of the previous frame and a multiplier for multiplying together the output of a divider and the output of a register. Using the structure the gain of the amplifier can be completed in real time.

In other aspect of the present invention, a solid-state image pick up device further comprises a plurality of specific areas are set in advance and an average computing means computes the average value of outputs of photoelectric conversion cells in a specific area selected by a user. Therefore, it is possible to change the specific area easily.

In other aspect of the present invention, an apparatus according to the present invention comprises an illuminating portion for irradiating light to a finger, an optical system for leading a light reflected by the finger to the sensor array of a solid-state image pick-up device of the present invention, an extractor which extracts feature points of a fingerprint of the finger from the output of the solid-state image pick-up device, a storage which stores feature points of a plurality of fingerprints in it, and a collator which collates the feature points extracted by the extractor and the feature points stored in the storage with each other. Using this improved structure, fingerprint collation can be performed better than conventional techniques.

In another aspect of the present invention, an apparatus further comprises a detector which detects the position of a finger on the basis of the output of a solid-state image pick-up device, and a controller which obtains and outputs the coordinates of the start point and the end point of a specific area from the result of detection of the detector to the solid-state image pick-up device. Using this improved structure, collation can be better performed.

The present invention is not limited to the above embodiments, and it is contemplated that numerous modifications may be made without departing from the spirit and scope of the invention. The solid-state image pick up device, as described above with reference to the figures, is a merely an exemplary embodiment of the invention, and the scope of the invention is not limited to these particular embodiments. Accordingly, other structural configurations may be used, without departing from the spirit and scope of the invention as defined in the following claims. invention is not limited to these particular embodiments. Accordingly, other structural configurations may be used, without departing from the spirit and scope of the invention as defined in the following claims.

What is claimed is:

1. A solid-state image pick-up device comprising:
a sensor array comprising a plurality of photoelectric conversion cells arranged in a matrix, said plurality of photoelectric conversion cells providing a first output, wherein said first output comprises a first portion corresponding to a first region in said matrix, and a second portion corresponding to a second region in said matrix;
an amplifier amplifying said first output to a second output at an amplifying factor based on a first control signal;
a first converter receiving said second output and providing a third output;
a computer control unit receiving said third output, and providing said third output at a first timing when said third output corresponds to said first portion of said first output, and a predetermined value at a second timing when said third output corresponds to said second portion of said first output; and
a controller providing said first control signal to said amplifier based on said third output and said predetermined value.

2. The solid-state image pick-up device as claimed in claim 1, wherein said computer control unit comprises:
a detector providing a first selecting signal at said first timing; and
a selector receiving said third output, and providing said third outputs in response to said first selecting signal.

3. The solid-state image pick-up device as claimed in claim 2, wherein said detector provides a second selecting signal at said second timing, and wherein said selector provides said predetermined value in response to said second selecting signal.

4. The solid-state image pick-up device as claimed in claim 3, wherein said detector comprises:
a comparator providing said first selecting signal when said first timing is detected based on a first predetermined coordinate corresponding to said first region, and providing said second selecting signal when said second timing is detected.

5. The solid-state image pick-up device as claimed in claim 4, wherein said detector further comprises:
a first resistor having a first input terminal and a first output terminal, and
a first adder receiving a first data provided from said first output terminal and providing a second data into said first input terminal and into said comparator; and
wherein said first resistor receives said second data in response to a clock signal.

6. The solid-state image pick-up device as claimed in claim 5, wherein said comparator provides said first selecting signal when said second data corresponds to said first region, and provides said second selecting signal when said second data corresponds to said second region.

7. The solid-state image pick-up device as claimed in claim 5, wherein said first predetermined coordinate comprises a start coordinate and an end coordinate, and
wherein said comparator provides said first selecting signal when said second data is larger than said start coordinate and smaller than said end coordinate.

8. The solid-state image pick-up device as claimed in claim 4, wherein said first output further comprises a third portion corresponding to a third region in a matrix; and
wherein said computer control unit provides said third output at a third timing when said third output correspond s to said third portion.

9. The solid-state image pick-up device as claimed in claim 8, wherein said comparator provides said first selecting signal when said third timing is detected based on a third predetermined coordinate corresponding to said third region.

10. The solid-state image pick-up device as claimed in claim 8, wherein said converter further comprises a retain circuit retaining said inner reference value, and providing said control signal in response to said inner reference value.

11. The solid-state image pick-up device as claimed in claim 2, wherein said detector comprises:
an address decoder receiving an address and a first predetermined coordinate corresponding to said first region, and providing a detecting signal when said address corresponds to said first region.

12. The solid-state image pick-up device as claimed in claim 11, wherein said detector further comprises:
a logic circuit providing said first selecting signal wherein both said detecting signal and said driving signal are received, wherein said first output is provided in response to said driving signal.

13. The solid-state image pick-up device as claimed in claim 1, wherein said controller comprises a computing unit providing an average value of said third output, provided from said computer control unit.

14. The solid-state image pick-up device as claimed in claim 13, wherein said computing unit comprises:
a second resistor having a second input terminal and a second output terminal,
a second adder receiving a third data provided from said second output terminal and an output of said computing control unit, and providing a forth data into said second input terminal of said second resistor, wherein said output of said computing control unit comprises said third output and said predetermined value;
a first divider receiving said forth data and providing said average value of said third output.

15. The solid-state image pick-up device as claimed in claim 14, wherein said first divider divides said forth data by a number of said plurality of photoelectric conversion cells in said first region of said matrix.

16. The solid-state image pick-up device as claimed in claim 15, wherein said controller further comprises a second converter providing said first control signal based on said average value of said third output.

17. The solid-state image pick-up device as claimed in claim 16, wherein said second converter comprises:
a second divider providing an inner reference value based on said average value of said third output and a reference value.

18. The solid-state image pick-up device as claimed in claim 17, wherein said second converter comprises:
a second divider divides said average value of said third output by said reference value.

19. The solid-state image pick-up device as claimed in claim 18, wherein said second converter further comprises:
a gain resistor storing a first control signal of a first frame;
a multiplier providing a second control signal of a second frame into said amplifier and said gain resistor based on said first control signal and said inner reference value.

20. A fingerprint collating apparatus comprising:
a solid-state image pick-up device, said solid-state image pick-up device comprising:
a sensor array comprising a plurality of photoelectric conversion cells arranged in a matrix, said plurality of photoelectric conversion cells providing a first output, wherein said first output comprises a first portion corresponding to a first region in said matrix, and a second portion corresponding to a second region in said matrix;
an amplifier amplifying said first output to a second output at an amplifying factor based on a first control signal;
a first converter receiving said second output and providing a third output;
a computer control unit receiving said third output, and providing said third output at a first timing when said third output corresponds to said first portion of said first output, and a predetermined value at a second timing when said third output corresponds to said second portion of said first output; and a controller providing said first control signal to said amplifier based on said third output and said predetermined value;
an illumination irradiating a light to a finger;
an optical system leading said light reflected by said finger to said sensor array of said solid-state image pick-up device;
an extractor extracting feature points of a fingerprint of said finger from said third output of said solid-state image pick-up device;
a memory storing feature points of a plurality of fingerprints; and a collator collating the feature points extracted by said extractor and said feature points stored in said memory with each other.

21. The fingerprint collating apparatus as claimed in claim 20, further comprises:
a detector detecting said position of a finger based on said third output of said solid-state image pick-up device; and
a calculator unit which obtains and outputs said first predetermined coordinate.
